(19) United States
(12) Patent Application Publication
(10) Pub. No.: US 2025/0151590 A1
(43) Pub. Date: May 8, 2025

(54) DISPLAY PANEL AND DISPLAY DEVICE

(71) Applicant: HKC CORPORATION LIMITED, Shenzhen (CN)

(72) Inventors: WENYU YI, Shenzhen (CN); Tianjun Huang, Shenzhen (CN); Zhonglin Cao, Shenzhen (CN); Chuan Wu, Shenzhen (CN); Yajuan Feng, Shenzhen (CN); Yao Li, Shenzhen (CN); Dongmei Wei, Shenzhen (CN); Jie Chen, Shenzhen (CN); Haijiang Yuan, Shenzhen (CN)

(21) Appl. No.: 18/931,150

(22) Filed: Oct. 30, 2024

(30) Foreign Application Priority Data
Nov. 3, 2023 (CN) 202311459646.1

(51) Int. Cl. H10K 59/80; G09G 3/3208; H10K 59/122; H10K 59/38

(52) U.S. Cl. CPC H10K 59/8792; H10K 59/122; H10K 59/38; G09G 3/3208; G09G 2320/0238

(57) ABSTRACT

A display panel and a display device are disclosed. The display panel includes a substrate, a light-emitting element layer, a pixel defining layer, an encapsulation layer, a refraction layer, and a color filter layer. The refraction layer is arranged on the encapsulation layer to refract light entering the refraction layer. The color filter layer is arranged on the refraction layer, and includes a black matrix disposed in a non-opening area and multiple color filters disposed in a non-opening area. Every two adjacent color filters are separated by the black matrix. The refraction layer includes multiple refraction portions. Each refraction portion is arranged under the black matrix, is located in the non-opening area, and extends toward the opening area. The refraction portions are each used to refract the external ambient light and receive the reflected light reflected by the light-emitting element and refract the reflected light to the black matrix.

### CROSS-REFERENCE TO RELATED APPLICATIONS

This application claims the priority and benefit of Chinese patent application number 2023114596461, titled “Display Panel and Display Device” and filed Nov. 3, 2023 with China National Intellectual Property Administration, the entire contents of which are incorporated herein by reference.

### TECHNICAL FIELD

This application relates to the field of display technology, and more particularly relates to a display panel and a display device.

### BACKGROUND

The description provided in this section is intended for the mere purpose of providing background information related to the present application but doesn't necessarily constitute prior art.

With the continuous development of OLED (Organic Light-Emitting Diode) display technology, OLED is increasingly used in displays such as smartphones, tablets, computers, and televisions. OLED displays have advantages of being thinness and lightweight, high contrast, fast response, wide viewing angle, high brightness, and full colors. In order to reduce the reflectivity of external light in the OLED display, the current mainstream solution is to attach a circular polarizer to a light-emitting surface of the OLED display. However, this solution reduces the light-emitting effect due to the relatively large light loss of the circular polarizer. Another solution is to dispose a color filter on the light-emitting surface of the OLED display to improve the light-emitting efficiency through the color filter, and the arrangement of the black matrix (BM) can reduce the reflection of ambient light in the OLED display.

However, when the OLED display panel is in a black state with the screen turned off, ambient light, especially relatively strong ambient light, may enter the display panel and reach the anode of the light-emitting element. After being reflected by the anode, an outgoing light is formed, which causes the display panel to exhibit color mixing, glare and other problems when in the black state.

### SUMMARY

It is therefore one purpose of the present application to provide a display panel and a display device to alleviate the phenomenon of color mixing, glare, etc. caused by the reflection of ambient light when the display panel is in a black state.

The present application discloses a display panel. The display panel includes an opening area and a non-opening area. The display panel further includes a substrate, a light-emitting element layer, a pixel defining layer, an encapsulation layer, a refraction layer, and a color filter layer. The light-emitting element layer includes a plurality of light-emitting elements. The plurality of light-emitting elements are arranged in an array on the substrate and are located in the opening area. The pixel defining layer is arranged on the substrate and is located in the non-opening area. Two adjacent light-emitting elements are separated by the pixel defining layer. The encapsulation layer is arranged on the light-emitting elements and the pixel defining layer. The refraction layer is arranged on the encapsulation layer and is used to refract the light entering the refraction layer. The color filter layer is arranged on the encapsulation layer. The color filter layer includes a black matrix and a plurality of color filters. The black matrix is arranged in the non-opening area. The color filters are arranged in the opening area. Two adjacent color filters are separated by the black matrix. The refraction layer includes a plurality of refraction portions. Each refraction portion is arranged under the black matrix, is located in the non-opening area and extends toward the opening area. Each refraction portion is used to refract ambient light and receive reflected light reflected by the light-emitting element and then refract it back to the black matrix.

In some embodiments, the refraction portion includes a first refraction portion and a second refraction portion. The first refraction portion is arranged in the opening area. The second refraction portion is arranged in the non-opening area. The first refraction portion extends from the opening area to the non-opening area and is connected to the second refraction portion. The refractive index of the first refraction portion is less than the refractive index of the color filter. The second refraction portion is greater than or equal to the refractive index of the color filter.

In some embodiments, the first refraction portion is partially arranged in the opening area and extends to the non-opening area. Two first refraction portions are arranged, respectively arranged on both sides of the second refraction portion. In the same non-opening area, the area of the orthographic projection of the second refraction portion on the substrate is smaller than the area of the orthographic projection of the black matrix on the substrate.

In some embodiments, the thickness of the refraction layer is greater than or equal to 1 um and less than or equal to 3 um. The area of the orthographic projection of the first refraction portion on the substrate does not exceed 20% of the area of the opening area.

In some embodiments, the second refraction portion defines a through slot, and a reflective layer is disposed in the through slot.

In some embodiments, the width of the part of the first refraction portion located in the opening area is D, the thickness of the black matrix is H, and D>H/tan θ, wherein θ is greater than 0 degrees and less than 45 degrees.

In some embodiments, the refraction layer further includes a third refraction portion. The third refraction portion is arranged in the opening area, and the third refraction portion is arranged between two adjacent refraction portions. The third refraction portion is formed of a transparent material.

In some embodiments, the refractive index of the third refraction portion is greater than the refractive index of the second refraction portion.

In some embodiments, the thickness of the second refraction portion is greater than the thickness of the first refraction portion.

The present application discloses a display device, including a driving circuit and the above-mentioned display panel, wherein the driving circuit is used to drive the display panel to display.

In the present application, a refraction layer is disposed below the color filter layer, and the refraction layer can refract the ambient light coming from the outside to the black matrix, or refract ambient light from the outside that enters the light-emitting element and is reflected by the light-emitting element back to the black matrix. Thus, the influence of the external ambient light is reduced. In particular, the external ambient light at a large angle enters the display panel, and is reflected by the bottom electrode of the light-emitting element and then emitted as a large-angle light, which is mixed with the reflected light of the adjacent pixels, so that in the black state and low grayscale, the display panel will have a color halo, causing glare and other problems. The refraction layer provided in the present application mainly refracts most of the ambient light at a large angle onto the black matrix, preventing the occurrence of color mixing, color halo and other phenomena after the ambient light at a large angle is reflected. The present application alleviates the phenomenon of color mixing and glare caused by the reflection of ambient light when the display panel is in the black state, and can improve the display effect of the display panel in the black state or low grayscale, making the black state darker and improving the quality of the display panel.

### BRIEF DESCRIPTION OF DRAWINGS

The accompanying drawings are used to provide a further understanding of the embodiments according to the present application, and constitute a part of the specification. They are used to illustrate the embodiments according to the present application, and explain the principles of the present application in conjunction with the text description. Apparently, the drawings in the following description merely represent some embodiments of the present disclosure, and for those having ordinary skill in the art, other drawings may also be obtained based on these drawings without investing creative. In the drawings:

FIG. 1 is a schematic diagram of a display panel according to the present application.

FIG. 2 is a schematic diagram of a display panel according to a first embodiment of the present application.

FIG. 3 is a schematic diagram of a top view of a refraction portion according to the present application.

FIG. 4 is a schematic diagram of a second refraction portion according to the first embodiment of the present application.

FIG. 5 is a partial schematic diagram of FIG. 2.

FIG. 6 is a schematic diagram of a variant of the display panel according to the first embodiment of the present application.

FIG. 7 is a schematic diagram of another variant of the display panel according to the first embodiment of the present application.

FIG. 8 is a schematic diagram of an outgoing light beam of the display panel according to the first embodiment of the present application.

FIG. 9 is a schematic diagram of a display panel according to a second embodiment of the present application.

FIG. 10 is a schematic diagram of a display panel according to a third embodiment of the present application.

FIG. 11 is a schematic diagram of a display panel according to a variant of the third embodiment of the present application.

FIG. 12 is a schematic diagram of a display device according to the present application.

In the drawings: 100, display panel; 101, opening area; 102, non-opening area; 110, substrate; 120, light-emitting element layer; 121, light-emitting element; 1211, bottom electrode; 1212, light-emitting layer; 1213, top electrode; 122, pixel defining layer; 123, encapsulation layer; 130, refraction layer; 130a, refraction portion; 131, first refraction portion; 132, second refraction portion; 132a, through slot; 133, third refraction portion; 134, reflective layer; 140, color filter layer; 141, color filter; 142, black matrix; 200, display device; 210, driving circuit.

### DETAILED DESCRIPTION OF EMBODIMENTS

It should be understood that the terms used herein, the specific structures and functional details disclosed therein are merely representative for describing some specific embodiments, but the present application can be implemented in many alternative forms and should not be construed as being limited to only these embodiments described herein.

As used herein, terms “first”, “second”, or the like are merely used for illustrative purposes, and shall not be construed as indicating relative importance or implicitly indicating the number of technical features specified. Thus, unless otherwise specified, the features defined by “first” and “second” may explicitly or implicitly include one or more of such features. Terms “multiple”, “a plurality of”, and the like mean two or more. In addition, terms “up”, “down”, “left”, “right”, “vertical”, and “horizontal”, or the like are used to indicate orientational or relative positional relationships based on those illustrated in the drawings. They are merely intended for simplifying the description of the present disclosure, rather than indicating or implying that the device or element referred to must have a particular orientation or be constructed and operate in a particular orientation. Therefore, these terms are not to be construed as restricting the present disclosure. For those of ordinary skill in the art, the specific meanings of the above terms as used in the present application can be understood depending on specific contexts.

The present application will be described in detail below with reference to the accompanying drawings and some optional embodiments.

FIG. 1 is a schematic diagram of a display panel according to the present application. As shown in FIG. 1, an ambient light ray with a certain angle from the outside is filtered by a color filter (taking a red filter as an example) to form a red ambient light ray. After the red ambient light ray passes through the encapsulation layer 123, the top electrode of the light-emitting element 121, and the light-emitting layer, it is reflected by the bottom electrode of the light-emitting element 121 to form an outgoing light with a certain angle. The red outgoing light is emitted from the upper red filter at a certain angle. The red outgoing light is superimposed with the green outgoing light of the adjacent green filter to form mixed colors, causing the display panel 100 to have a color halo, glare and other problems. In this regard, this application has made the following improvements.

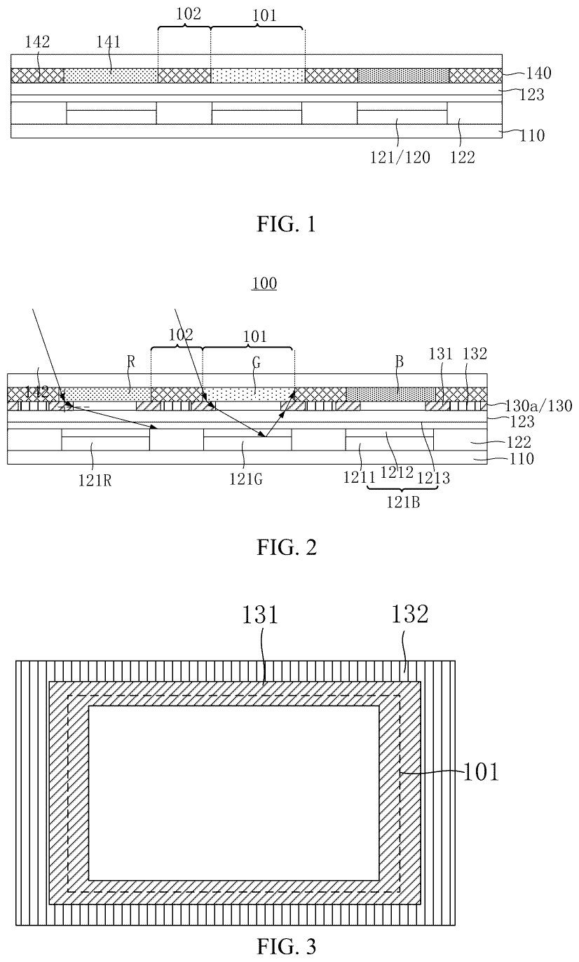

FIG. 2 is a schematic diagram of a display panel according to a first embodiment of the present application. As shown in FIG. 2, the present application discloses a display panel 100. The display panel 100 includes an opening area 101 and a non-opening area 102. The display panel 100 further includes a substrate 110, a light-emitting element layer 120, a pixel defining layer 122, an encapsulation layer 123, a refraction layer 130, and a color filter layer 140.

The light-emitting element layer 120 includes a plurality of light-emitting elements 121. The plurality of light-emitting elements 121 are arranged in an array on the substrate 110 and are located in the opening area 101. The pixel defining layer 122 is disposed on the substrate 110 and is located in the non-opening area 102. Two adjacent light-emitting elements 121 are separated by the pixel defining layer 122. The encapsulation layer 123 is disposed on the light-emitting elements 121 and the pixel defining layer 122. The refraction layer 130 is disposed on the encapsulation layer 123 and is used to refract the light entering the refraction layer 130. The color filter layer 140 is disposed on the encapsulation layer 123. The color filter layer 140 includes a black matrix 142 and a plurality of color filters 141. The black matrix 142 is arranged in the non-opening area 102. The color filters 141 are arranged in the opening area 101. Two adjacent color filters 141 are separated by the black matrix 142. The refraction layer 130 includes a plurality of refraction portions 130a. The refraction portions 130a are arranged under the black matrix 142, are located in the non-opening area 102, and extend toward the opening area 101. The refraction portion 130a is used to refract external ambient light, and receive the reflected light reflected by the light-emitting element 121 and refract it to the black matrix 142.

In the present application, a refraction layer 130 is disposed below the color filter layer 140, and the refraction layer 130 can refract the ambient light coming from the outside to the black matrix 142, or refract ambient light from the outside that enters the light-emitting element 121 and is reflected by the light-emitting element 121 back to the black matrix 142. Thus, the influence of the external ambient light is reduced. In particular, the external ambient light at a large angle enters the display panel 100, and is reflected by the bottom electrode of the light-emitting element 121 and then emitted as a large-angle light, which is mixed with the reflected light of the adjacent pixels, so that in the black state and low grayscale, the display panel 100 will have a color halo, causing glare and other problems. The refraction layer 130 provided in the present application mainly refracts most of the ambient light at a large angle onto the black matrix 142, preventing the occurrence of color mixing, color halo and other phenomena after the ambient light at a large angle is reflected. The present application alleviates the phenomenon of color mixing and glare caused by the reflection of ambient light when the display panel 100 is in the black state, and can improve the display effect of the display panel 100 in the black state or low grayscale, making the black state darker and improving the quality of the display panel 100.

The opening area 101 may refer to the position of the color filter 141. When displaying, the opening area 101 forms an outgoing light, which can display a variety of colors, roughly corresponding to the area between the adjacent pixel defining layers 122 of the display panel 100. The non-opening area 102 is the position corresponding to the black matrix 142, which has no outgoing light when displaying and is displayed as a black area, roughly corresponding to the area of the pixel defining layer 122. The opening area 101 and the non-opening area 102 may be both located in the display area of the display panel 100.

The color filter layer 140 includes a plurality of color filters 141. The color filters 141 can be divided into a red filter R, a green filter G, and a blue filter B. The light-emitting elements 121 can be divided into a red light-emitting element 121R, a green light-emitting element 121G, and a blue light-emitting element 121B. The red filter R is disposed corresponding to the red light-emitting element 121R. The green filter G is disposed corresponding to the green light-emitting element 121G. The blue filter B is disposed corresponding to the blue light-emitting element 121B.

The light-emitting element 121 may include a bottom electrode 1211, a light-emitting layer 1212, and a top electrode 1213. The bottom electrode 1211 may be formed by a composite film layer of a transparent conductive layer/silver electrode layer/transparent conductive layer, and has a high reflective effect. The light-emitting layer 1212 specifically includes a hole injection layer, a hole transport layer, a light-emitting layer, an electron transport layer, and an electron injection layer, etc. The top electrode 1213 is formed by a transparent conductive layer on the entire surface. Through the joint action of the top electrode 1213 and the bottom electrode 1211, electrons and holes are excited to emit light in the light-emitting layer. Furthermore, the light-emitting layer materials of light-emitting elements of different colors are different, so that light of different colors can be emitted.

It can be understood that the present application is an OLED display panel 100 with POL-less technology, specifically using a color filter 141 to replace the polarizer in the OLED to improve the light-emitting efficiency of the display panel 100.

Specifically, the refraction portion 130a includes a first refraction portion 131 and a second refraction portion 132. The first refraction portion 131 is arranged in the opening area 101. The second refraction portion 132 is arranged in the non-opening area 102. The first refraction portion 131 extends from the opening area 101 to the non-opening area 102 and is connected to the second refraction portion 132. The refractive index of the first refraction portion 131 is less than the refractive index of the color filter 141. The second refraction portion 132 is greater than or equal to the refractive index of the color filter 141.

Continuing to refer to FIG. 2, the refractive index of the first refraction portion 131 is smaller than that of the color filter 141, and the refractive index of the color filter 141 is smaller than that of the second refraction portion 132. According to the principle that light will deviate in the direction of the normal when entering from a medium with a comparatively small refractive index into a medium with a comparatively large refractive index. When the ambient light from the outside is incident on the red filter at a certain angle, it first passes through the interface between the first re-fraction portion 131 and the color filter 141. At this time, the refractive index of the color filter 141 is higher than that of the first refraction portion 131. Therefore, when the ambient light enters the first refraction portion 131 from the red filter, it will deviate in the direction away from the normal line. A part of the ambient light will be emitted from the side of the first refraction portion 131, which is called the side incident light, and another part of the ambient light will be emitted from the bottom of the first refraction portion 131, which is called the bottom incident light. When the side incident light leaves the first refraction portion 131, since the refractive index of the film layer the side incident light is entering is higher than that of the first refraction portion 131, the side incident light may further deviate in the direction parallel to the surface direction of the display panel 100, and then no longer enter the bottom electrode of the light-emitting element 121. The bottom incident light deviates from the normal direction after incidence, so that the angle between the bottom incident light and the normal direction of the light-emitting element 121 is even larger, so that the bottom incident light is reflected at a larger angle at the bottom electrode of the light-emitting element 121, and so the angle between the reflected light and the normal direction is also larger. As such, the reflected light is also incident into the first refraction portion 131, and is refracted into the black matrix 142 again by the dual refractions of the first refraction portion 131 and the second refraction portion 132.

Of course, the ambient light reflected by the bottom electrode of the light-emitting element 121 is also divided into two types, one part is emitted to the side surface of the first refraction portion 131, and the other part is emitted to the bottom surface of the first refraction portion 131. Of course, there is also a part of reflected light that is emitted directly from the color filter 141. Most of the light emitted to the bottom surface of the first refraction portion 131 is refracted again by the second refraction portion 132 to the black matrix 142 and absorbed. The light emitted to the side of the first refraction portion 131 is partially incident on the side of the black matrix 142 through the first refraction portion 131, and partially forms the emitted light. Relatively speaking, in the solution, through the action of the first refraction portion 131 and the second refraction portion 132, most of the large-angle light can be absorbed by the incident light, so as to alleviate the phenomenon of color mixing, glare, etc. caused by the reflection of ambient light when the display panel 100 is in the black state.

FIG. 3 is a schematic top view of a refraction portion according to the present application. Referring to FIGS. 2-3, a refraction portion 130a is disposed below the black matrix 142. The refraction portion 130a is composed of at least two parts, wherein the second refraction portion 132 is completely disposed below the black matrix 142, and the first refraction portion 131 extends from the black matrix 142 area to the opening area 101. The first refraction portion 131 is in the shape of a square annulus in a top view, and the second refraction portion 132 is also in the shape of a square annulus in a top view, and the second refraction portion 132 is arranged around the first refraction portion 131. It can be understood that the inner ring of the first refraction portion 131 is located in the opening area 101, and the outer ring of the first refraction portion 131 is located in the non-opening area 102.

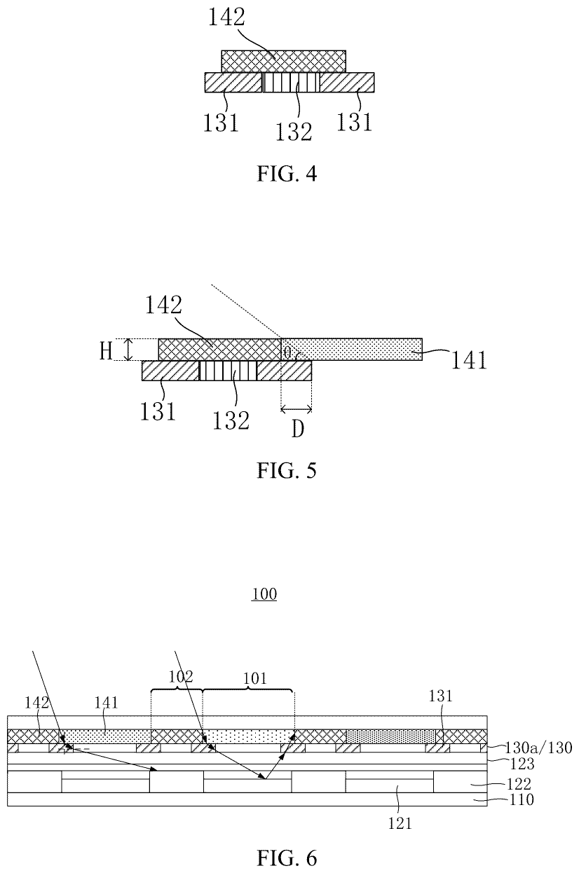

FIG. 4 is a schematic diagram of a second refraction portion according to the first embodiment of the present application. As shown in FIG. 4, in the present solution, in the same non-opening area 102, two first refraction portions 131 are provided, and are respectively disposed on both sides of the second refraction portion 132. Each first refraction portion 131 is partially disposed in the opening area 101 and extends toward the non-opening area 102. It can be understood that the two first refraction portions 131 belong to first refraction portions 131 of different opening areas 101 respectively. At the position of the same non-opening area 102, the first refraction portions 131 extend from the opening area 101 to the non-opening area 102 respectively.

In the same non-opening area 102, the area of an orthographic projection of the second refraction portion 132 on the substrate 110 is smaller than the area of an orthographic projection of the black matrix 142 on the substrate 110.

Specifically, in the present application, when the thickness of the color filter layer 140 of the display panel 100 is about 2.8 um, the thickness of the refraction layer 130 is about 1-3 um. In the present application, the thickness of the refraction layer 130 should not be too large, which may otherwise increase the thickness of the display panel 100. But relatively speaking, the thicker the refraction layer 130 is, the stronger its ability to change the light path is. Furthermore, the thickness of the refraction layer 130 should not be too thin, otherwise it may not be able to realize the intended function.

FIG. 5 is a partial schematic diagram of FIG. 2. As shown in FIG. 5, the width of the part of the first refraction portion 131 located in the opening area 101 is D. The thickness of the black matrix 142 is H. The following equation D>H/Tan θ is satisfied, wherein θ is greater than 0 degrees and less than 45 degrees.

In this solution, the width of the part of the first refraction portion 131 in the opening area 101 is D, which refers to the width of the area of the orthographic projection of the first refraction portion 131 on the substrate 110 located in the opening area 101, and the width is the width of the first refraction portion 131 extending from the edge of the black matrix 142 to the opening area 101. In this embodiment, θ refers to the angle between the external ambient light incident on the display panel 100 and the surface of the display panel 100. θ is set to be greater than 0 degrees and less than 45 degrees, that is, the first refraction portion 131 can at least refract most of the light at an angle of more than 45 degrees, so that it no longer enters the light-emitting element 121, or the ambient light is no longer emitted outwards after being reflected from the light-emitting element 121.

From another perspective, the area of the orthographic projection of the first refraction portion 130 on the substrate 110 does not exceed 20% of the area of the opening area 101. Relatively speaking, according to the principle of light reversibility, the first refraction portion 130 will reflect light and have a deviation effect, which will have a certain impact on the outgoing light. Therefore, the area of the part of the first refraction layer 130 in the opening area 101 should not be too large to avoid affecting the normal outgoing light.

It can be understood that the refractive index of the first refraction portion 131 of the present application is smaller than the refractive index of the color filter layer 140, and smaller than the refractive index of other film layers, such as the encapsulation layer 123. In contrast, the refractive index of the second refraction portion 132 is higher than the refractive index of the color filter layer 140.

FIG. 6 is a schematic diagram of a variant of the display panel according to the first embodiment of the present application. As shown in FIG. 6, in this embodiment, the first refraction portion 131 can be used alone, and the second refraction portion 132 does not need to be used. In this embodiment, at the position of the same non-opening area 102, the first refraction portion 131 extends toward the opening area 101, and the first refraction portion 131 is disposed below the black matrix 142 and extends toward the opening area 101. Specifically, the area of the orthographic projection of the first refraction portion 131 on the substrate 110 is larger than the area of the orthographic projection of the black matrix 142 on the substrate 110. In this embodiment, the refractive power of the first refraction portion 131 is mainly used, and the first refraction portion 131 is used to resolve part of the large-angle ambient light, thereby improving the color mixing phenomenon.

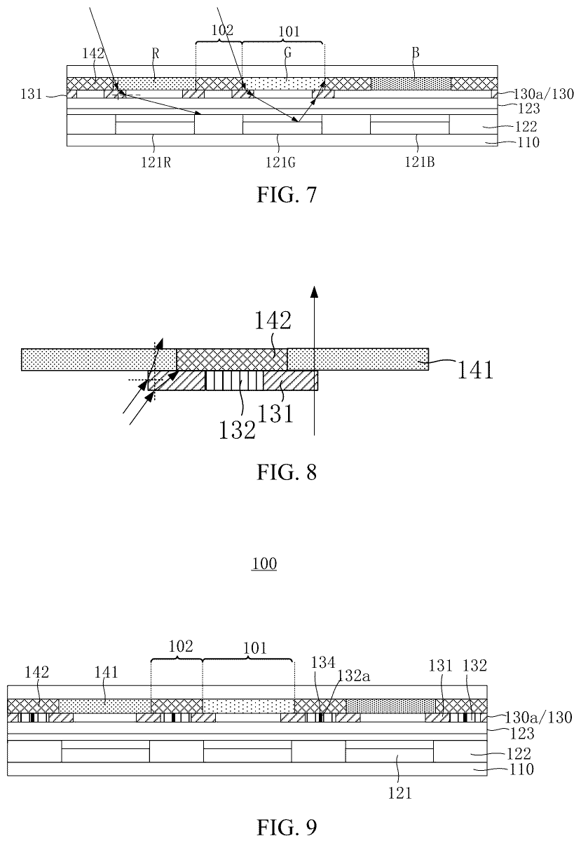

FIG. 7 is a schematic diagram of another variant of the display panel according to the first embodiment of the present application. As shown in FIG. 7, based on the first embodiment, the present embodiment makes another improvement on the position of the refraction portion 130a. Specifically, the refraction portion 130a is disposed corresponding to the red filter and the green filter, while for the blue filter, the annular refraction portion 130a is not arranged around the blue filter.

Specifically, in the display panel 100, the wavelength of blue light is the shortest, and the blue light-emitting element 121B requires a larger excitation voltage than the red light-emitting element 121R and the green light-emitting element 121G under the same brightness. Correspondingly, if there is less blue light in the display panel 100, the problem of yellowing may occur. In this solution, the refraction portion 130a is not disposed below the blue filter to avoid the refraction portion 130a affecting the light-emitting efficiency.

FIG. 8 is a schematic diagram of an outgoing light ray of the display panel according to the first embodiment of the present application. The influence of the first refraction portion 131 of the present application on the outgoing light is shown in FIG. 8. A part of the outgoing light is directly emitted from the opening, and this part of the outgoing light is mainly used as the light of the display image, and most of the light is like this. Due to the existence of the first refraction portion 131 in the opening area 101, the outgoing light of the projection area of the light-emitting element 121 corresponding to the first refraction portion 131 will inevitably be emitted to the first refraction portion 131.

Correspondingly, the outgoing light may also be roughly divided into two types of light, part of which is vertical outgoing light. Since the vertical outgoing light is parallel to the normal direction and is not affected by refraction, most of the light will directly pass through the first refraction portion 131 to form outgoing light. Among the outgoing light rays at a certain angle emitted by the light-emitting element 121, due to the refraction effect of the first refraction portion 131, part of the outgoing light rays will be absorbed by the black matrix 142. Furthermore, part of the outgoing light is emitted from the side of the first refraction portion 131. Due to the effect of the first refraction portion 131, the light that would have entered the black matrix 142 at a large angle can be refracted and then emitted from the color filter 141. This can also make up for the loss of part of the outgoing light. Relatively speaking, the display panel 100 of this embodiment has a satisfactory display effect under a narrow viewing angle.

FIG. 9 is a schematic diagram of a display panel according to a second embodiment of the present application. As shown in FIG. 9, based on the first embodiment, the present embodiment further improves the second refraction portion 132. The second refraction portion 132 defines a through slot 132a, and a reflective layer 134 is disposed in the through slot 132a. In this solution, the function of the reflective layer 134 is mainly to reflect the reflected light entering from the second refraction portion 132 back to the black matrix 142, so that the reflected light is absorbed by the black matrix 142.

Specifically, the orthographic projection of the through slot 132a on the substrate 110 is an annular shape, the orthographic projection of the second refraction portion 132 on the substrate 110 is also annular, and the through slot 132a is arranged in the middle part of the second refraction portion 132. The reflective layer 134 is used to reflect the light emitted from the second refraction portion 132 to the reflective layer 134 back to the black matrix 142.

Specifically, the thickness of the second refraction portion 132 is higher than the thickness of the first refraction portion 131. In this solution, since the refractive index of the second refraction portion 132 is relatively high, when entering the second refraction portion from other film layers, the light deviates to the normal direction.

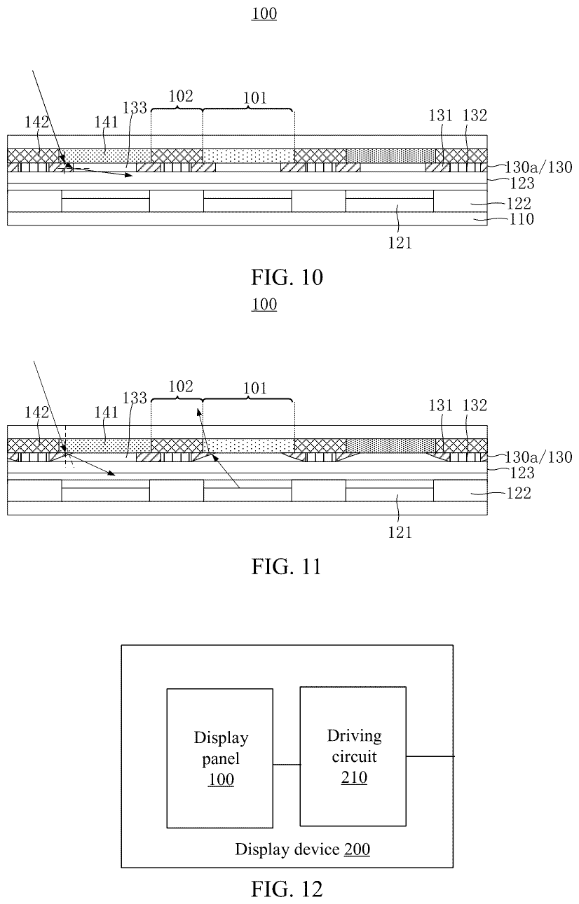

FIG. 10 is a schematic diagram of a display panel according to a third embodiment of the present application. As shown in FIG. 10, the present application further adds a third refraction portion 133 on the basis of the second embodiment. Specifically, the refraction layer 130 further includes a third refraction portion 133. The third refraction portion 133 is arranged in the opening area 101. The third refraction portion 133 is arranged between two adjacent refraction portions 130a. The third refraction portion 133 is formed of a transparent material.

In this solution, the refraction effect of the third refraction portion 133 is utilized to make the light emitted from the first refraction portion 131 further deviates in a direction parallel to the display panel 100, further preventing the external ambient light from being incident on the light-emitting element 121.

Specifically, the refractive index of the third refraction portion 133 is greater than the refractive index of the second refraction portion 132. The third refraction portion 133 is surrounded by the first refraction portion 131. Relatively speaking, the third refraction portion 133 will not affect the vertically emitted light of the light-emitting element 121. Furthermore, when some outgoing light rays at a certain angle pass through the third refraction portion 133, because the refractive index of the third refraction portion 133 is the highest, it will cause the light rays at an angle to further deviate toward the normal direction, increase the number of vertical outgoing light rays, and improve the front viewing effect of the display panel 100.

FIG. 11 is a schematic diagram of a display panel of a variant embodiment of the third embodiment according to the present application. As shown in FIG. 11, based on the third embodiment, the shape of the first refraction portion 131 is improved to a certain extent, so that the width of the first refraction portion 131 gradually decreases in the direction of the incident ambient light. In other words, in the direction from the color filter 141 to the corresponding light-emitting element 121, the width of the first refraction portion 131 gradually decreases and forms an inclined surface, and the thickness of the first refraction portion 131 gradually increases from the opening area 101 to the non-opening area 102. In this solution, the first refraction portion 131 is further improved, so that the interface position between the first refraction portion 131 and the adjacent film layer can be changed, so that the normal line at which the light path is refracted deviates to the non-opening area 102, and so when the ambient light is incident, the ambient light no longer incident on the light-emitting element 121.

FIG. 12 is a schematic diagram of a display device according to the present application. As shown in FIG. 12, the present application further discloses a display device 200, including a driving circuit 210 and the above-mentioned display panel 100. The driving circuit 210 is used to drive the display panel 100 to display.

In the present application, a refraction layer 130 is disposed below the color filter layer 140, and the refraction layer 130 can refract the ambient light coming from the outside to the black matrix 142, or refract ambient light from the outside that enters the light-emitting element 121 and is reflected by the light-emitting element 121 back to the black matrix 142. Thus, the influence of the external ambient light is reduced. In particular, the external ambient light at a large angle enters the display panel 100, and is reflected by the bottom electrode of the light-emitting element 121 and then emitted as a large-angle light, which is mixed with the reflected light of the adjacent pixels, so that in the black state and low grayscale, the display panel 100 will have a color halo, causing glare and other problems. The refraction layer 130 provided in the present application mainly refracts most of the ambient light at a large angle onto the black matrix 142, preventing the occurrence of color mixing, color halo and other phenomena after the ambient light at a large angle is reflected. The present application alleviates the phenomenon of color mixing and glare caused by the reflection of ambient light when the display panel 100 is in the black state, and can improve the display effect of the display panel 100 in the black state or low grayscale, making the black state darker and improving the quality of the display panel 100.

It should be noted that the inventive concept of the present application can be formed into many embodiments, but the length of the application document is limited and so these embodiments cannot be enumerated one by one. Therefore, should no conflict be present, the various embodiments or technical features described above can be arbitrarily combined to form new embodiments. After the various embodiments or technical features are combined, the original technical effects may be enhanced.

The foregoing is merely a further detailed description of the present application with reference to some specific optional implementations, but it is not to be determined that the specific implementation of the present application is limited to these implementations. For those having ordinary skill in the technical field to which the present application pertains, multiple deductions or substitutions may be made without departing from the concept of the present application, and all these deductions or substitutions shall be regarded as falling in the scope of protection of the present application.

What is claimed is:

1. A display panel, comprising an opening area and a non-opening area, the display panel further comprising:
a substrate;
a light-emitting element layer, comprising a plurality of light-emitting elements that are arranged in an array on the substrate and located in the opening area;
a pixel defining layer, arranged on the substrate and disposed in the non-opening area, wherein every two adjacent light-emitting elements are separated by the pixel defining layer;
an encapsulation layer, arranged on the plurality of light-emitting elements and the pixel defining layer;
a refraction layer, arranged on the encapsulation layer and configured for refracting light entering the refraction layer; and
a color filter layer, arranged on the refraction layer, the color filter layer comprising a black matrix and a plurality of color filters, the black matrix being arranged in the non-opening area, the plurality of color filters being arranged in the opening area, wherein every two adjacent color filters are separated from each other by the black matrix;
wherein the refraction layer comprises a plurality of refraction portions, which are arranged under the black matrix, located in the non-opening area, and each extend toward the opening area; wherein the plurality of refraction portions are each used to refract ambient light and receive reflected light reflected by the respective light-emitting element and refract the reflected light back to the black matrix.

2. The display panel as recited in claim 1, wherein each of the plurality of refraction portions comprises a first refraction portion and a second refraction portion, wherein the first refraction portion is arranged in the opening area, wherein the second refraction portion is arranged in the non-opening area, wherein the first refraction portion extends from the opening area to the non-opening area and is connected to the second refraction portion; wherein the first refraction portion has a refractive index that is less than a refractive index of the respective color filter, and the second refraction portion has a refractive index that is greater than or equal to the refractive index of the respective color filter.

3. The display panel as recited in claim 2, wherein each first refraction portion is partially arranged in the opening area and extends to the non-opening area; wherein there is arranged two first refraction portions respectively on both sides of the second refraction portion; wherein in each same portion of the non-opening area, an area of an orthographic projection of the second refraction portion on the substrate is less than an area of an orthographic projection of the black matrix on the substrate.

4. The display panel as recited in claim 3, wherein the refraction layer has a thickness that is greater than or equal to 1 um and less than or equal to 3 um.

5. The display panel as recited in claim 3, wherein an area of an orthographic projection of each first refraction portion on the substrate does not exceed 20% of an area of the respective portion of the opening area.

6. The display panel as recited in claim 2, wherein the second refraction portion defines a through slot, and wherein there is arranged a reflective layer in the through slot.

7. The display panel as recited in claim 2, wherein the second refraction portion has a thickness that is greater than a thickness of the first refraction portion.

8. The display panel as recited in claim 3, wherein let a width of a part of the first refraction portion that is located in the opening area be D, a thickness of the black matrix be H, then the following equation is satisfied: D>H/tan θ, where θ is greater than 0 degrees and less than 45 degrees.

9. The display panel as recited in claim 2, wherein in the direction pointing from each color filter toward the respective light-emitting element, a width of the respective first refraction portion gradually decreases and forms an inclined surface.

10. The display panel as recited in claim 2, wherein a thickness of each first refraction portion gradually increases in a direction from the opening area to the non-opening area.

11. The display panel as recited in claim 2, wherein the refraction layer further comprises a third refraction portion arranged in the opening area, wherein the third refraction portion is arranged between every two adjacent refraction portions; wherein the third refraction portion is formed of a transparent material.

12. The display panel as recited in claim 7, wherein the third refraction portion has a refractive index that is greater than a refractive index of the second refraction portion.

13. The display panel as recited in claim 2, wherein the color filter layer comprises a plurality of color filters, comprising a red filter, a green filter, and a blue filter;
wherein the plurality of light-emitting elements comprise a red light-emitting element, a green light-emitting element, and a blue light-emitting element;
wherein the red filter is disposed corresponding to the respective red light-emitting element, the green filter is disposed corresponding to the green light-emitting element, and the blue filter is disposed corresponding to the blue light-emitting element;
wherein the refraction portion is only disposed corresponding to each of the red filter and the green filter, and not disposed corresponding to the blue filter.

14. A display device, comprising a display panel and a driving circuit used to drive the display panel to display; wherein the display panel comprises an opening area and a non-opening area, the display panel further comprising:
a substrate;
a light-emitting element layer, comprising a plurality of light-emitting elements arranged in an array on the substrate and located in the opening area;
a pixel defining layer, arranged on the substrate and disposed in the non-opening area, wherein every two adjacent light-emitting elements are separated by the pixel defining layer;
an encapsulation layer, arranged on the plurality of light-emitting elements and the pixel defining layer;
a refraction layer, arranged on the encapsulation layer and configured for refracting light entering the refraction layer; and
a color filter layer, arranged on the refraction layer, the color filter layer comprising a black matrix and a plurality of color filters, the black matrix being arranged in the non-opening area, the plurality of color filters being arranged in the opening area, wherein every two adjacent color filters are separated from each other by the black matrix;
wherein the refraction layer comprises a plurality of refraction portions, which are arranged under the black matrix, located in the non-opening area, and each extend toward the opening area; wherein the plurality of refraction portions are each used to refract ambient light and receive reflected light reflected by the respective light-emitting element and refract the reflected light back to the black matrix.

15. The display device as recited in claim 14, wherein each of the plurality of refraction portions comprises a first refraction portion and a second refraction portion, wherein the first refraction portion is arranged in the opening area, wherein the second refraction portion is arranged in the non-opening area, wherein the first refraction portion extends from the opening area to the non-opening area and is connected to the second refraction portion; wherein the first refraction portion has a refractive index that is less than a refractive index of the respective color filter, and the second refraction portion has a refractive index that is greater than or equal to the refractive index of the respective color filter.

16. The display device as recited in claim 15, wherein each first refraction portion is partially arranged in the opening area and extends to the non-opening area; wherein there is arranged two first refraction portions respectively on both sides of the second refraction portion; wherein in each same portion of the non-opening area, an area of an orthographic projection of the second refraction portion on the substrate is less than an area of an orthographic projection of the black matrix on the substrate.

17. The display device as recited in claim 16, wherein the refraction layer has a thickness that is greater than or equal to 1 um and less than or equal to 3 um.

18. The display device as recited in claim 16, wherein an area of an orthographic projection of the first refraction portion on the substrate does not exceed 20% of an area of the respective portion of the opening area.

19. The display device as recited in claim 15, wherein the second refraction portion defines a through slot, and wherein there is arranged a reflective layer in the through slot.
